(19) United States
(12) Patent Application Publication
(10) Pub. No.: US 2002/0189061 A1
(43) Pub. Date: Dec. 19, 2002

(54) Method for manufacturing quartz crystal oscillators and quartz crystal oscillator produced therefrom

(75) Inventors: Jong-Tae Kim, Suwon (KR); Hu-Nam Choi, Suwon (KR); Gum-Young Youn, Suwon (KR); Jong-Pil Lee, Suwon (KR)

Correspondence Address: LOWE HAUPTMAN GOPSTEIN GILMAN & BERNER, LLP, Suite 310, 1700 Diagonal Road, Alexandria, VA, 22314, US

(73) Assignee: Samsung Electro-Mechanics Co., Ltd.

(21) Appl. No.: 09/948,860

(22) Filed: Sep. 10, 2001

(30) Foreign Application Priority Data
May 24, 2001 (KR) 2001-28646

(51) Int. Cl. H04R 17/00; H05K 3/36; H05K 3/34; H01L 41/04; H02N 2/00

(52) U.S. Cl. 29/25.35; 29/830; 29/840; 310/370; 310/361

(57) ABSTRACT

A method of manufacturing high reliability quartz crystal oscillators and a quartz crystal oscillator produced therefrom is disclosed. In the present invention, a quartz crystal oscillating plate is mounted to a ceramic base within the top cavity of the ceramic base by means of a plurality of metal bumps. The quartz crystal oscillator has a ceramic base formed by laminating a second ceramic layer along the periphery of the top surface of a first ceramic layer. The ceramic base has a top cavity, with a plurality of electrode terminals formed on the first ceramic layer at predetermined positions and electrically connected to external electrodes. A quartz crystal oscillating plate, having a plurality of electrode patterns, is mounted to the electrode terminals of the first ceramic base within the top cavity through a plurality of metal bumps such that a remaining part of the oscillating plate except for the terminals is spaced apart from the ceramic base by a gap. A ceramic lid covers the top of the top cavity of the ceramic base, thus sealing the oscillating plate.

### FIELD OF THE INVENTION

The present invention relates to the manufacture of quartz crystal oscillators and, more particularly, to a method for manufacturing quartz crystal oscillators having superior reliability by the improved technique of disposing a quartz crystal oscillating plate within the top cavity of a ceramic base, the present invention also relating to a quartz crystal oscillator of a new structural mode produced through such a method.

### BACKGROUND OF THE INVENTION

In general, quartz crystal oscillators have been used as devices for generating reference frequencies in, for example, electronic watches or clocks. Such quartz crystal oscillators have been typically classified into two types: tuning fork-type quartz crystal oscillators and reed-type quartz crystal oscillators. Of the two types, the tuning fork-type quartz crystal oscillators are also so-called “Watson-type quartz crystal oscillators”, and have been disclosed in several references, such as U.S. Pat. Nos. 3,969,641, 4,176,030, and 4,421,621. An example of the conventional tuning fork-type quartz crystal oscillators is shown in FIG. 1a to 1d. As shown in FIG. 1a, the conventional tuning fork-type quartz crystal oscillator 100 includes a laminated ceramic base 111, which consists of a first ceramic layer 112 with second and third ceramic layers 113 and 114 sequentially formed along the periphery of the top surface of the first layer 112 so as to define a top cavity. The oscillator 100 also has a quartz crystal oscillating plate 120 disposed within the top cavity of the laminated ceramic base 111, as shown in FIG. 1b and 1c. A plurality of predetermined electrode patterns 122, 124, 122′ and 124′ are conventionally formed on the quartz crystal blank 121 of the oscillating plate 120, as shown in FIG 1d. In the case of crystal oscillator with a tuning fork-type quartz crystal blank, it is required to maintain a vacuum within the quartz crystal oscillator 100. In the quartz crystal oscillator 100 with a triple-layer as shown in FIGS. 1a to 1d, the oscillating plate 120 is mounted on the protrusions 113 a and 113b extending from the second ceramic layer 113 on the base 111. A predetermined gap is made between the plate 120 and the base 111. In the case of the above-mentioned triple-layered quartz crystal oscillator, paste 130 or 132 is typically applied to the top surface of each protrusion 113a or 113b so as to adhere the oscillating plate 120 onto the protrusions 113a and 113b through a conventional die bonding process. During such a conventional die bonding process, solder, Si-based Ag paste, or epoxy-based Ag paste have been typically used. In such a case, it is required to thermally cure the paste when the oscillating plate is fixed to the ceramic base. After the oscillating plate is completely adhered on the protrusion of the second ceramic layer, the ceramic base is covered with a lid 116.

In the meanwhile, another type of quartz crystal oscillator with a double-layer in place of the above-mentioned triple-layered quartz crystal oscillator has been proposed and used. The quartz crystal oscillator, having the double-layered ceramic base, is somewhat different from the quartz crystal oscillator having the triple-layered ceramic base in its structure and its die bonding process. An example of conventional quartz crystal oscillators having such double-layered ceramic bases is shown in FIGS. 2a to 2d. FIG. 2a is an exploded perspective view of the quartz crystal oscillator having such a double-layered ceramic base. FIG. 2b is an exploded perspective view of the quartz crystal oscillator, showing a quartz crystal oscillating plate disposed within the top cavity of the ceramic base. FIG. 2c is a side sectional view of the quartz crystal oscillator. FIG. 2d is a sectional view, showing the construction of the portion “A” of FIG. 2c in detail. As shown in FIG. 2a, the double-layered ceramic base 211 of the quartz crystal oscillator 200 does not have any protrusions acting as the terminals, and so a quartz crystal oscillating plate 220 is directly mounted to the first ceramic layer 212 of the base 211. During a die bonding process, two tungsten bumps 230a are formed on the base 211. In addition, paste 230 is applied to the top surface of each tungsten bump 230 a so as to adhere the oscillating plate 220 to the bumps 230a while leaving a desired gap between the plate 220 and the first ceramic layer 212 of the base 211. FIG. 2d shows the construction of the quartz crystal oscillator 200 having the oscillating plate 220 in detail.

However, the conventional quartz crystal oscillator has the following problems regardless of the types of their laminated ceramic bases. That is, the quartz crystal oscillating plate must be mounted to the ceramic base through a die bonding process, wherein paste is applied to the ceramic base so as to mount the plate to the base. Therefore, it is required to thermally cure the paste during the process of manufacturing the quartz crystal oscillators. In addition, the smaller the size of the ceramic base may be, the more difficult it may be to control the amount of paste during a die bonding process to meet the recent trend of compactness of the quartz crystal oscillators. Furthermore, in tuning fork-type quartz crystal oscillators that are required to maintain a vacuum in their cavity, the use of solder or epoxy-based paste used for mounting an oscillating plate on the ceramic base inevitably results in generating gas at a high processing temperature, thus undesirably deteriorating the quality of the oscillators. In addition, the conventional quartz crystal oscillators could not but have a somewhat complex construction that have protrusions extending from the second ceramic layer or a tungsten bump for mounting the oscillating plate thereon so as to leave a desired gap between the plate and the base.

### SUMMARY OF THE INVENTION

Accordingly, the present invention is provided to solve the above problems occurring in the prior art. An object of the present invention is to provide a method of manufacturing quartz crystal oscillators by mounting a quartz crystal oscillating plate to a ceramic base through an improved bonding process, thus the oscillators improving the reliability and the productivity.

Another object of the present invention is to provide a quartz crystal oscillator, which is produced through such a new manufacturing method.

In order to accomplish the above objects, an embodiment of the present invention provides a method of manufacturing quartz crystal oscillators, comprising the steps of:

forming a ceramic base which a second ceramic layer and a third ceramic layer are sequentially laminated along the periphery of the top surface of a first ceramic layer, the ceramic base having a top cavity, wherein the top cavity is surrounded by the second ceramic layer and the third ceramic layer which are punched out so as to form protrusions partially extending from one side of the second ceramic layer, and the second ceramic layer having a predetermined electrode terminals on the protrusions;

preparing a quartz crystal oscillating plate having a predetermined electrode patterns;

disposing a plurality of metal bumps on the top surface of each of the electrode terminals on the protrusions of the second ceramic layer;

positioning the quartz crystal oscillating plate within the top cavity of the ceramic base and electrically connecting the quartz crystal oscillating plate with the metal bumps such that a remaining part of the quartz crystal oscillating plate except for the electrode terminals is spaced apart from the ceramic base by a gap; and

sealing the ceramic base with a ceramic lid.

Another embodiment of the present invention provides a method of manufacturing quartz crystal oscillators, comprising the steps of:

forming a ceramic base which a second ceramic layer is laminated along the periphery of a first ceramic layer, the ceramic base having a top cavity, wherein the top cavity is surrounded by the second ceramic layer which is punched out to form a rim, and the first ceramic layer having a predetermined electrode terminals at a desired position;

preparing a quartz crystal oscillating plate having a plurality of electrode patterns;

disposing a plurality of metal bumps on each of the electrode terminals of the first ceramic layer;

positioning the quartz crystal oscillating plate within the top cavity of the ceramic base and electrically connecting the quartz crystal oscillating plate with the metal bumps such that a remaining part of the quartz crystal oscillating plate except for the electrode terminals is spaced apart from the ceramic base by a gap; and

sealing the ceramic base with a ceramic lid.

A further embodiment of the present invention provides a quartz crystal oscillator, comprising:

a ceramic base laminated a second ceramic layer along the periphery of the top surface of a first ceramic layer, the ceramic base having a top cavity surrounded by the second ceramic layer, the first ceramic layer having a plurality of electrode terminals which are electrically connected to external electrodes at predetermined positions;

a quartz crystal oscillating plate having a plurality of electrode patterns, the oscillating plate being mounted to the electrode terminals of the first ceramic layer within the top cavity through a plurality of metal bumps such that a remaining part of the oscillating plate except for the terminals is spaced apart from the ceramic base by a gap; and

a ceramic lid covering the ceramic base to seal the oscillator.

### BRIEF DESCRIPTION OF THE DRAWINGS

Above features and other advantages of the present invention will be more clearly understood from the following detailed description taken in conjunction with the accompanying drawings, in which:

FIGS. 1a to id show a tuning fork-type quartz crystal oscillator in accordance with an embodiment of the prior art, in which:

FIG. 1a is an exploded perspective view of the quartz crystal oscillator;

FIG. 1b is an exploded perspective view of the quartz crystal oscillator, showing a quartz crystal oscillating plate disposed within the top cavity of a ceramic base;

FIG. 1c is a side sectional view of the quartz crystal oscillator; and

FIG. 1d is a perspective view of FIG. 1b in detail, showing the quartz crystal oscillating plate having electrode patterns;

FIGS. 2a to 2d show a quartz crystal oscillator in accordance with another embodiment of the prior art, in which:

FIG. 2a is an exploded perspective view of the quartz crystal oscillator;

FIG. 2b is an exploded perspective view of the quartz crystal oscillator, showing a quartz crystal oscillating plate disposed within the top cavity of a ceramic base;

FIG. 2c is a side sectional view of the quartz crystal oscillator; and

FIG. 2d is a sectional view, showing the construction of the portion “A” of FIG. 2c in detail;

FIGS. 3a to 3d show a quartz crystal oscillator in accordance with an embodiment of the present invention, in which:

FIG. 3a is an exploded perspective view of the quartz crystal oscillator, showing a quartz crystal oscillating plate disposed within the top cavity of a ceramic base having a plurality of metal bumps;

FIG. 3b is a perspective view, showing the portion “B” of FIG. 3a in detail;

FIG. 3c is a sectional view, showing a process of mechanically mounting the quartz crystal oscillating plate to the ceramic base with the metal bumps using ultrasonic waves generated by a sonicator; and

FIG. 3d is a side sectional view of the quartz crystal oscillator;

FIG. 4 shows the construction of a conventional flip bonding device;

FIGS. 5a to 5d are enlarged views of the portion “C” of FIG. 4, showing a process of forming a metal bump on a base through a conventional flip bonding process;

FIGS. 6a and 6b show a process of forming a metal bump on a pad of a base through the conventional flip bonding process;

FIG. 7 shows a process of mounting a semiconductor chip on a base with metal bumps through the conventional flip bonding process;

FIGS. 8a to 8d show a process of forming a metal bump on an electrode terminal of a ceramic base in accordance with the present invention;

FIG. 9 is a perspective view showing the shape of the metal bump formed on the electrode terminal of the ceramic base according to the present invention;

FIG. 10a is an exploded perspective view of a quartz crystal oscillator, showing a quartz crystal oscillating plate disposed within the top cavity of a ceramic base with the metal bumps in accordance with another embodiment of the present invention;

FIG. 10b is an enlarged view of the portion “D” of FIG. 10a; and

FIGS. 11a to 11c show a quartz crystal oscillator in accordance with a further embodiment of the present invention, in which:

FIG. 11a is an exploded perspective view of the quartz crystal oscillator, showing a quartz crystal oscillating plate disposed within the top cavity of a ceramic base with a plurality of metal bumps;

FIG. 11b is a side sectional view of the quartz crystal oscillator; and

FIG. 11c is an enlarged sectional view, showing the construction of the portion “E” of FIG. 11b in detail.

### DETAILED DESCRIPTION OF THE INVENTION

Reference now should be made to the drawings, in which the same reference numerals are used throughout the different drawings to designate the same or similar components.

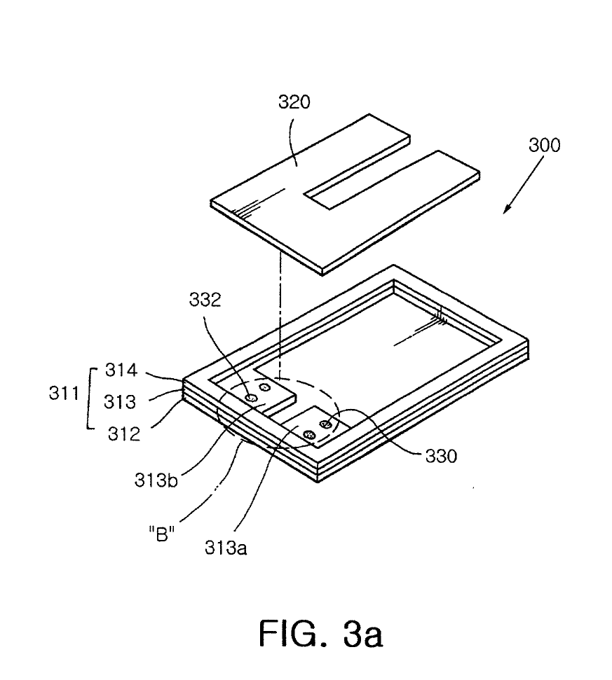

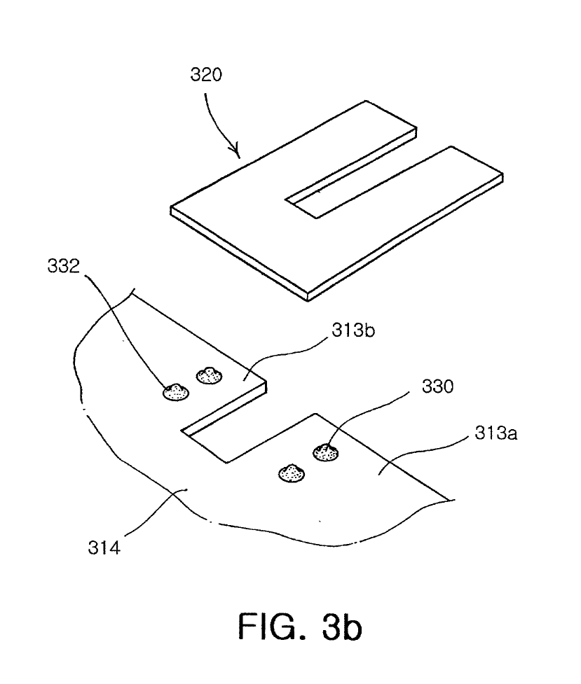

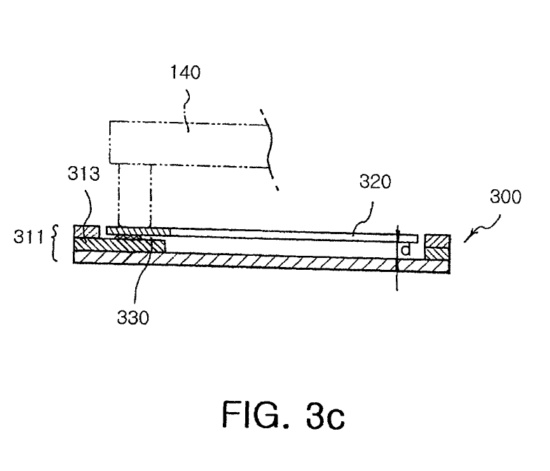

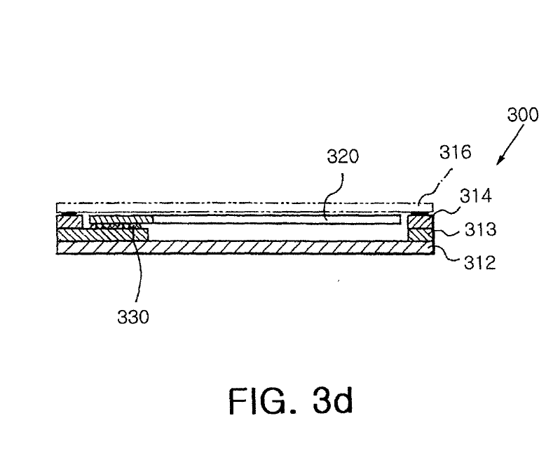

FIGS. 3a to 3d show a quartz crystal oscillator having a triple-layered ceramic base in accordance with the primary embodiment of the present invention. As shown in the drawings, the ceramic base 311 of the quartz crystal oscillator 300 according to this invention may be made of one conventional green sheet, or produced by laminating a plurality of sheets. In the primary embodiment of this invention, each of second and third ceramic layers 313 and 314 is punched out to form a rim. The two ceramic layers 313 and 314 are sequentially laminated along the periphery of the top surface of a first ceramic layer 312, thus forming a desired ceramic base 311. In the triple-layered ceramic base 311 of the primary embodiment, one side of the second ceramic layer 313 partially extends inwardly to form two protrusions 313a and 313b, which provide for supporting a quartz crystal oscillating plate 320 thereon. A plurality of metal bumps 330 and 332 are arranged on the top surfaces of the protrusions 313a and 313b, and the plate 320 is to mount on the protrusions 313a and 313b to adhere through the bumps. Of course, predetermined electrode patterns are formed on the quartz crystal blank of the oscillating plate 320. In addition, electrode terminals having a predetermined pattern are provided with on the protrusions 313a and 313b. In the present invention, it should be understood that the electrode terminals may be somewhat freely designed in accordance with the desired characteristics of a resulting oscillator. Therefore, it is noted that the shapes or patterns of the electrode terminals do not limit the gist of the present invention. The electrode terminals on the protrusions 313a and 313b are connected to external electrodes. In the present invention, the protrusions 313a and 313b are independently separated each other, but may be a single one. In the oscillator with triple-layered ceramic base, the metal bumps 330 and 332 are formed on the electrode terminals of the protrusions 313a and 313b, and connect the electrode terminals of the protrusions 313a and 313b to the electrode terminals of the oscillating plate 320.

In the present invention, the oscillating plate is mounted to the ceramic base through a improved flip bonding process in place of a conventional die bonding process. That is, as shown in FIGS. 3b and 3c, the metal bumps 330 and 332 are formed on the top surfaces of the protrusions 313a and 313b of the ceramic base 311. Thereafter, the plate 320 is mounted to the protrusions 313a and 313b through the bumps 330 and 332. Therefore, the plate 320 is disposed within the top cavity of the ceramic base 311. In order to mount the plate 320 to the ceramic base 311, the plate 320 is laid on the bumps 320 and 330, and is pressed to the bumps, with mechanical frictional force caused by ultrasonic waves and applied to the plate 320 as shown in FIG. 3c. The plate 320 is mounted to the ceramic base 311 such that the electrode terminals of the plate 320 are electrically connected to the metal bumps 330 and 332. In such a case, it is preferred to apply pressure of about 2 kgf or less and ultrasonic waves to the plate 320 for a period of about 230 msec or less while heating the plate 320 at a temperature of about 300° C. or less and applying an electric current of about 2 W or less to the plate 320. In addition, it is preferred to form a gap “d” of about 10˜40 μm between the plate 320 and the top surface of the first ceramic layer 312. FIG. 3d is a side sectional view of the quartz crystal oscillator 300, which the plate 320 is assembled within the top cavity of the ceramic base 311 and is covered with a lid 316.

In the present invention, it is necessary to carefully perform the flip bonding process, different from a conventional flip bonding process used for mounting a semiconductor chip on a base or a substrate. During a conventional semiconductor chip mounting process, a semiconductor chip is mounted to a base using a plurality of bumps uniformly arranged on the whole periphery of a substrate. However, in the present invention, one end of the oscillating plate 320 is mounted to the ceramic base through the metal bumps, while the remaining part of the plate 320 is horizontally suspended. In a brief description, the plate 320 of this invention is a cantilever plate. Therefore, it is required to carefully perform the flip bonding process of mounting the plate 320 to the ceramic base 311. The flip bonding process of mounting the plate 320 to the ceramic base 311 through the metal bumps is one of the characterized parts of the present invention. The flip bonding process of mounting the plate 320 to the ceramic base 311 in this invention will be described in detail herein below.

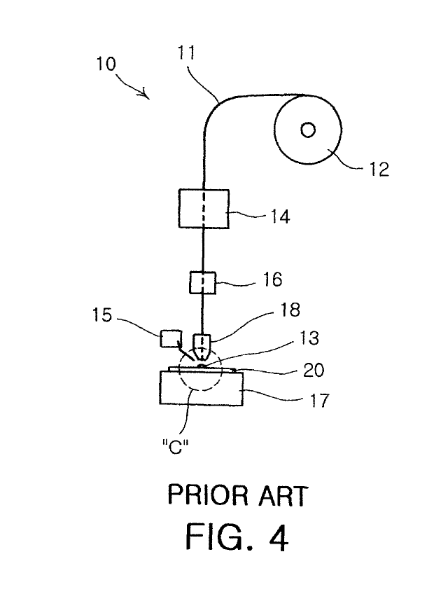

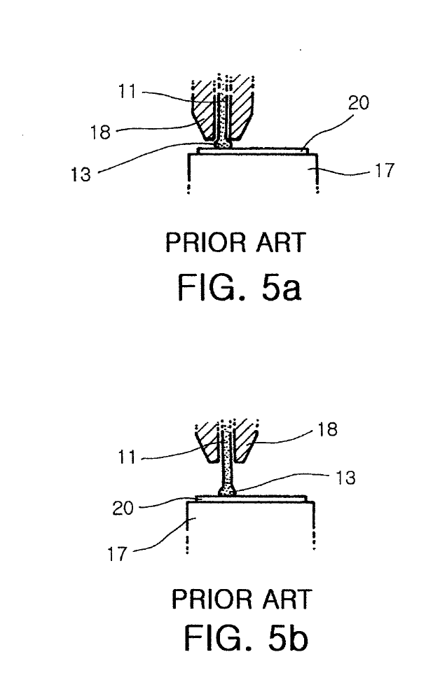

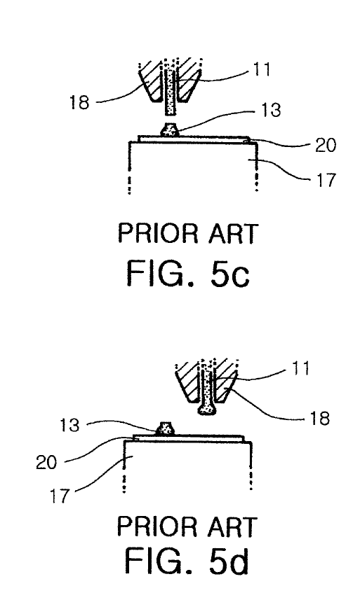

FIG. 4 shows the construction of a conventional flip bonding device. FIGS. 5a to 5d show a method of forming a metal bump on a base through a conventional flip bonding process. As shown in FIG. 4, a conventional flip bonding device 10 includes a wire roll 12, an air jet-type wire support unit 14, a clamp 16, a capillary tip 18, and a heat stage 17. A metal wire 11 is wound around the wire roll 12. Both the wire support unit 14 and the clamp 16 are sequentially installed on a wire feeding line of the device so as to support the wire 11 fed from the roll 12. The capillary tip 18 is positioned at the terminal of the wire feeding line, and forms desired metal bumps. The heat stage 17 heats the base 20. During the flip bonding process, the capillary tip 18 moves downward toward the heat stage 17. At a time the tip of the wire 11 comes into contact with the top surface of the base 20 during such a movement of the capillary tip 18, a torch 15 approaches the tip of the wire 11 from a side of the device 10 as shown in FIGS. 5a to 5d, thus instantaneously partially melting the tip of the wire 11. Thereafter, the capillary tip 18 along with the metal wire 11 is moved upward while leaving a dome-shaped metal bump 13 on the top surface of a pad of the base 20. After a formation of a metal bump 13 on a pad, the device forms another metal bump on another pad through the same process as described above.

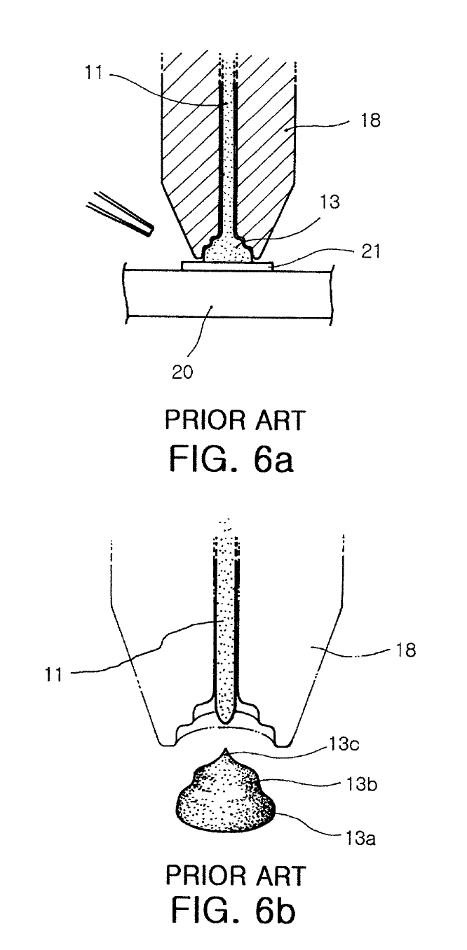

FIGS. 6a and 6b show a method of forming a metal bump 13 on a pad 21 of a base 20 in detail through the conventional flip bonding process. Of course, it is possible to form the metal bump 13 with various shapes by changing the shape of the capillary tip 18 as shown in FIG. 6a. However, since the capillary tip 18 along with the metal wire 11 is moved upward after the tip of the wire 11 is partially melted by a torch during the conventional flip bonding process, the top 13c of the bump 13 is pointed as shown in FIG. 6b.

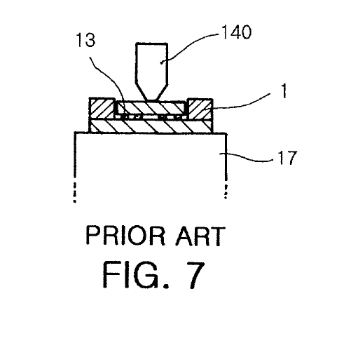

FIG. 7 shows a method of mounting a semiconductor chip 1 on a base 20 with the metal bump 13 using the sonicator 140. During a conventional flip bonding process, the semiconductor chip 1 is mounted to the base 20 at two or more sides of the base, and so a desired electric and mechanical connection of the chip 1 to the base 20 can be accomplished even though each metal bump 13 is pointed at its top. However, when the metal bumps 13 having such a pointed top 13a are used for mounting an oscillating plate to a ceramic base of a quartz crystal oscillator, the bumps 13 may cause several problems. Since only one end of the oscillating plate is mounted to the ceramic base of a quartz crystal oscillator using the metal bumps, it is necessary to precisely mount the oscillating plate within the top cavity of the ceramic base at a desired position while maintaining desired horizontality of the plate. However, it is very difficult for the conventional metal bumps having such a pointed top to mount the oscillating plate to the ceramic base while maintaining desired horizontality of the plate within the ceramic base. Therefore, the present invention provides metal bumps having a shape suitable for mounting the oscillating plate to the ceramic base while maintaining the desired horizontality of the plate, thus improving the operational reliability of the resulting quartz crystal oscillators.

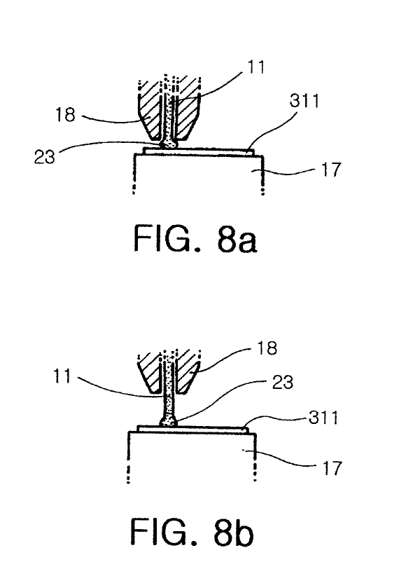

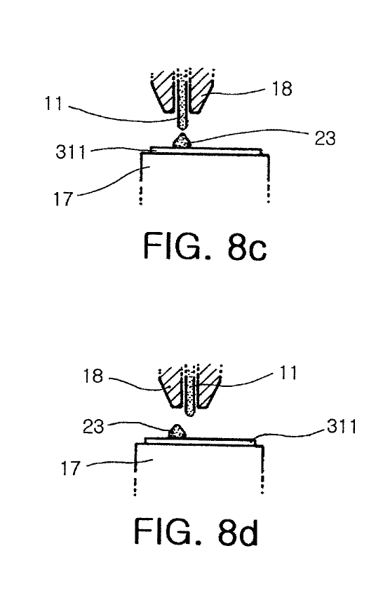

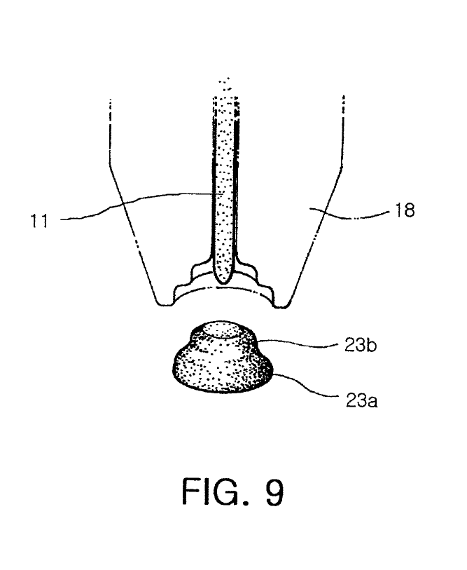

FIGS. 8a to 8d show a process of forming a metal bump 23 on an electrode terminal of a ceramic base 311 in accordance with the present invention. The general steps of the flip bonding process of mounting a quartz crystal oscillating plate to the ceramic base in the present invention remain the same as those of the conventional flip bonding process. However, the process of this invention is altered to press the pointed top of each metal bump 23 with the capillary tip 18 at the step of FIG. 8d, thus smoothing the top 23b of the bump 23 as shown in FIG. 9. Of course, it should be understood that the smoothing of the pointed top of the metal bump 23 could be accomplished by another means in place of the use of the capillary tip 18 without affecting the functioning of this invention. For example, the pointed top of the metal bump 23 can be smoothed through partially cutting or grinding. However, it should be understood that the present invention uses the metal bumps having such a smooth top 23. In the present invention, it is preferable to make each metal bump 23 having both a smooth top portion 23b and a smooth bottom portion 23a, with the volume of the top portion being smaller than that of the bottom portion. For example, the smooth bottom portion of each metal bump of this invention preferably has a generally cylindrical shape with a diameter of about 50 μm or less and a height of about 40˜90 μm. In order to form such smooth metal bumps on the terminals of the ceramic base, it is preferable to apply ultrasonic waves to the metal bumps while heating and squeezing the bumps at predetermined processing conditions during the process of forming the metal bumps on the ceramic base as shown in FIGS. 8a and 8b. In the present invention, it is preferred to apply pressure of about 250 g or less from the capillary tip 18 to the metal bump 23 and apply ultrasonic waves to the bump 23 for a period of about 50 msec or less while heating the heat stage 17 at a temperature of about 300° C. or less, preferably about 150˜250° C., and applying an electric current of about 2 W or less to the bump 23.

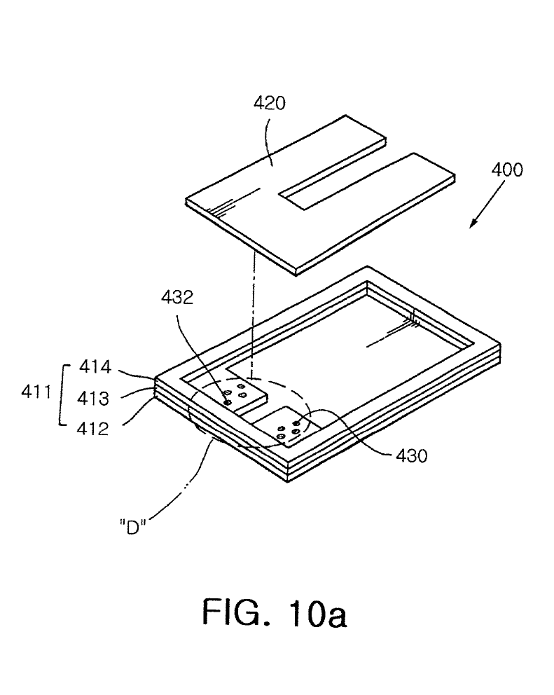

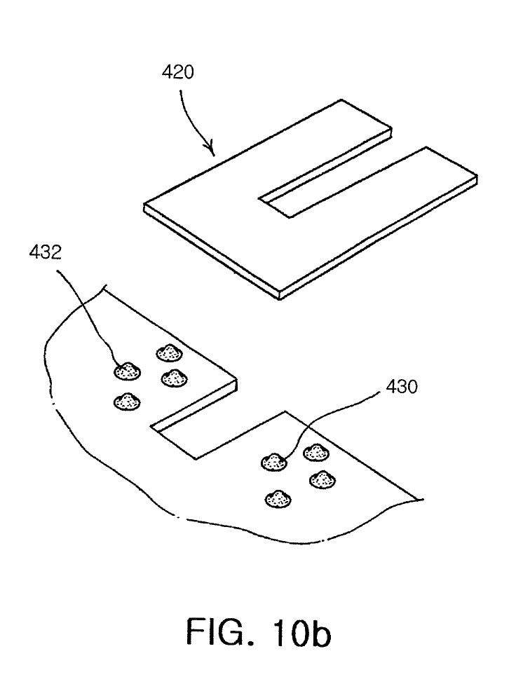

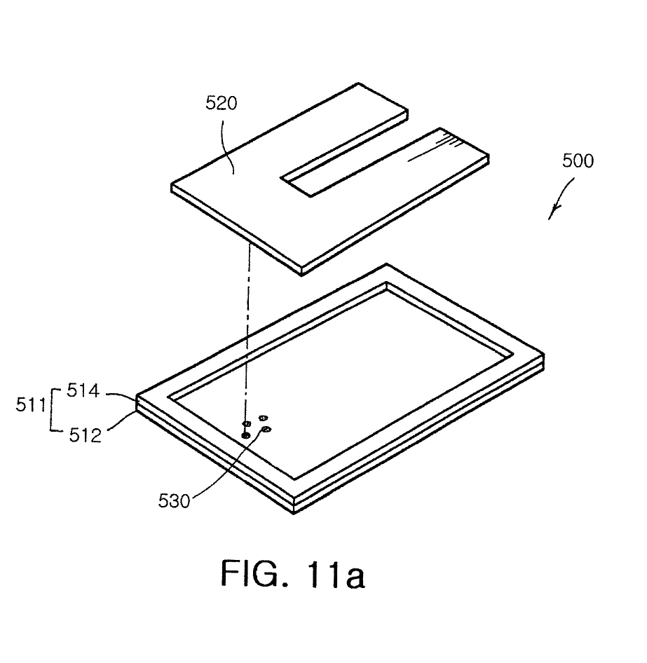

In the present invention, it is preferable to form two or more metal bumps on each electrode terminal of the ceramic base. In the embodiment of FIG. 10a, four metal bumps 430 or 432 are formed on each electrode terminal of a triple-layered ceramic base 411 corresponding to each electrode terminal of a quartz crystal oscillating plate 420. FIG. 10b is an enlarged view of the portion “D” of FIG. 10a. In the present invention, it is preferable to form the metal bumps on each electrode terminal of the ceramic base such that the bumps on each terminal occupy at least 20% of the entire area of each electrode terminal of the oscillating plate corresponding to each electrode terminal of the ceramic base. When two or more metal bumps are formed on each electrode terminal of the ceramic base as described above, it is more preferable to form a zigzag arrangement of the bumps. In addition, the metal bumps are preferably made of gold since the gold bumps effectively accomplish good conductivity.

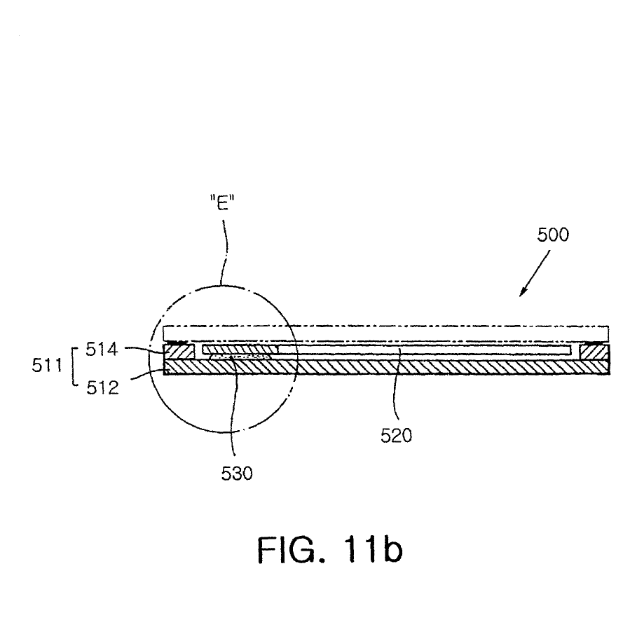

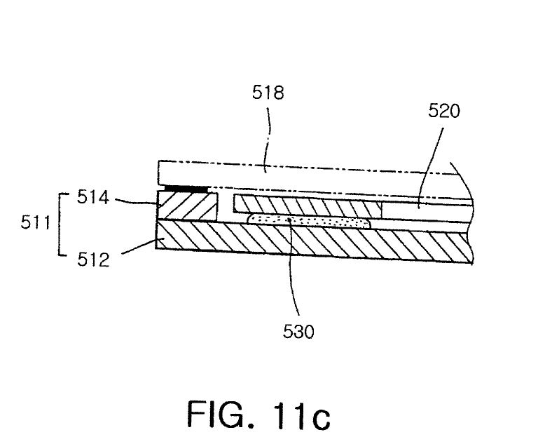

In each of the embodiments of FIGS. 3a and 10a, the ceramic base of the quartz crystal oscillator has a triple-layered structure. However, it should be understood that the ceramic base of the quartz crystal oscillator may have a double or more-layered structure without affecting the functioning of this invention. FIGS. 11a to 11d are views, showing a quartz crystal oscillator having a double-layered ceramic base in accordance with another embodiment of the present invention. FIG. 11a is an exploded perspective view of the quartz crystal oscillator. FIG. 11b is a side sectional view of the quartz crystal oscillator. FIG. 11c is an enlarged sectional view, showing the construction of the portion “E” of FIG. 11b in detail. As shown in FIG. 11a, the quartz crystal oscillator 500 includes a double-layered ceramic base 511. This ceramic base 511 is made by laminating a second ceramic layer 514 along the periphery of the top surface of a first ceramic layer 512 while leaving a top cavity of the base 511. A quartz crystal oscillating plate 520 is mounted to the top surface of the first ceramic layer 512 of the ceramic base 511 within the top cavity of the base 511 through a plurality of metal bumps 530. The cavity of the ceramic base 511 is, thereafter, covered with a lid 518. In the ceramic base 511, the second ceramic layer 514 is laminated along the periphery of the top surface of the first ceramic layer 512. An electrode terminal is provided on a predetermined position of the top surface of the first ceramic layer 512, and is electrically connected to an external electrode. The second ceramic layer 514 defines a cavity of the ceramic base 511, and so the plate 520 is mounted to the first ceramic layer 512 within the cavity. The electrode terminal of the plate 520 is electrically connected to the electrode terminal of the first ceramic layer 512 through a plurality of metal bumps produced in the same manner as that described above. Of course, the remaining part of the plate 520 is horizontally suspended above the top surface of the first ceramic layer 512. A plurality of predetermined electrode patterns are formed on the quartz crystal blank of the oscillating plate 520. It should be understood that the electrode patterns may be somewhat freely designed in accordance with the characteristics of resulting quartz crystal oscillators.

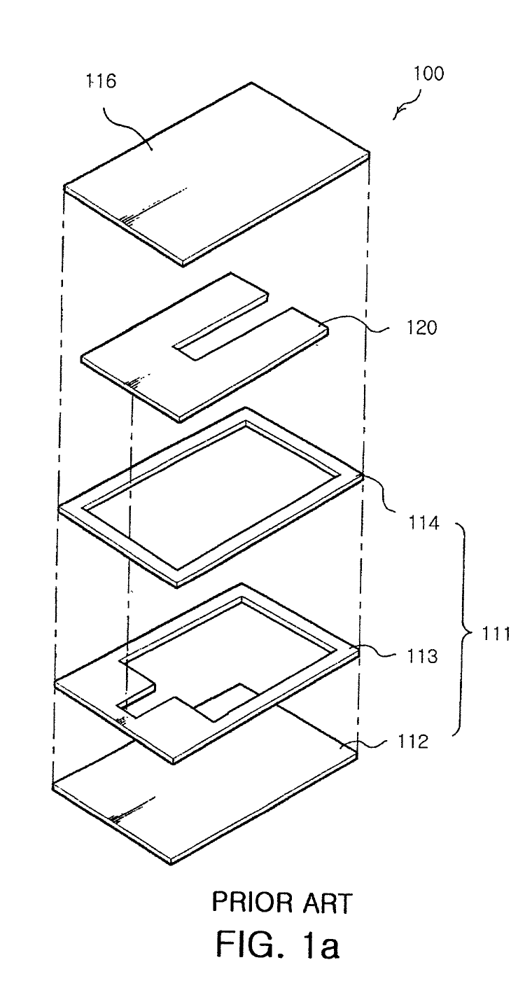

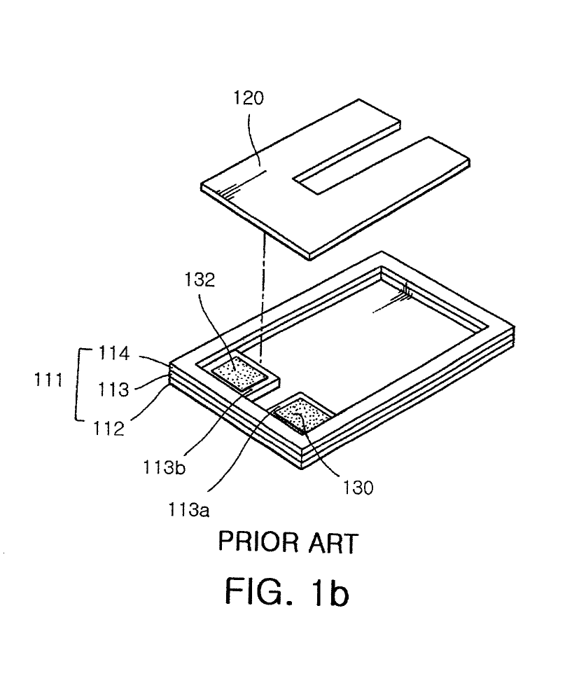

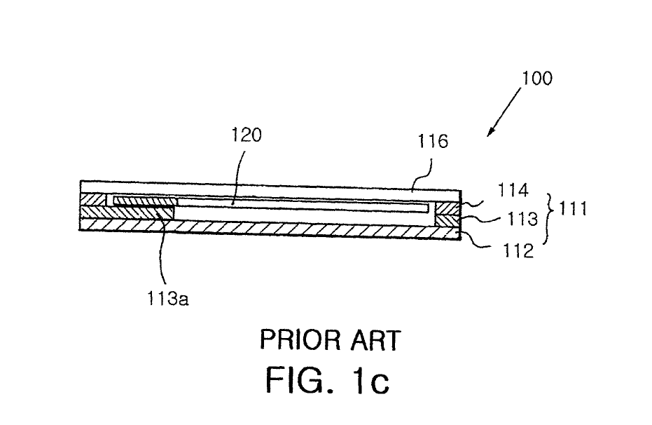

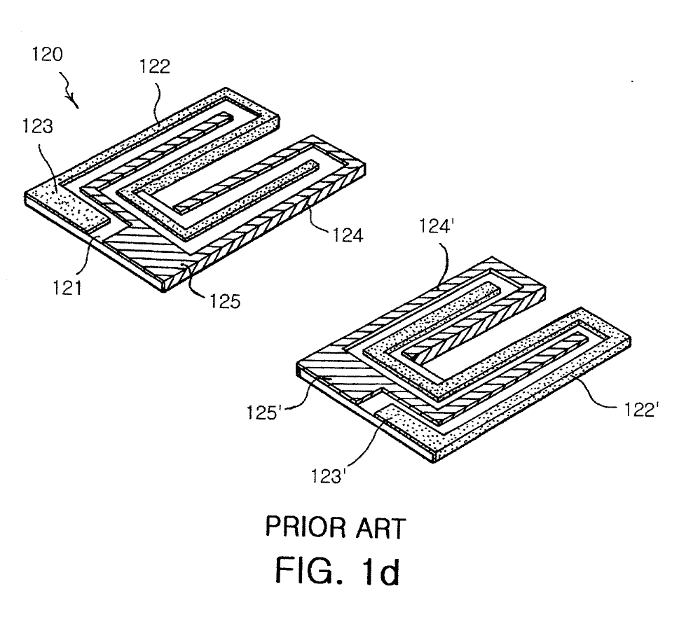

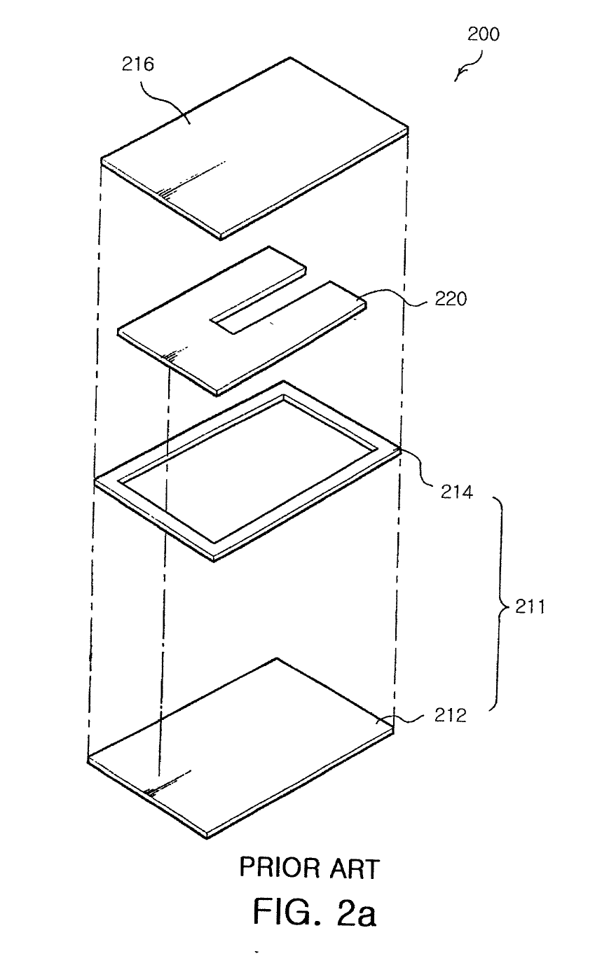

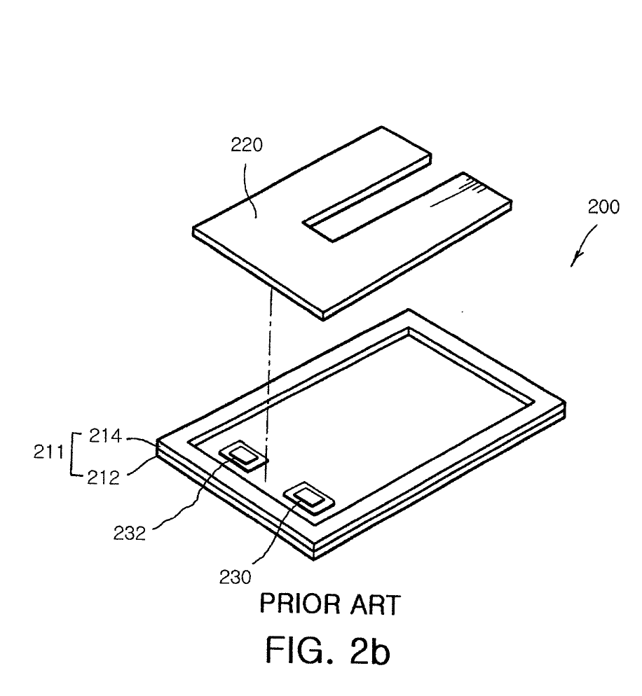

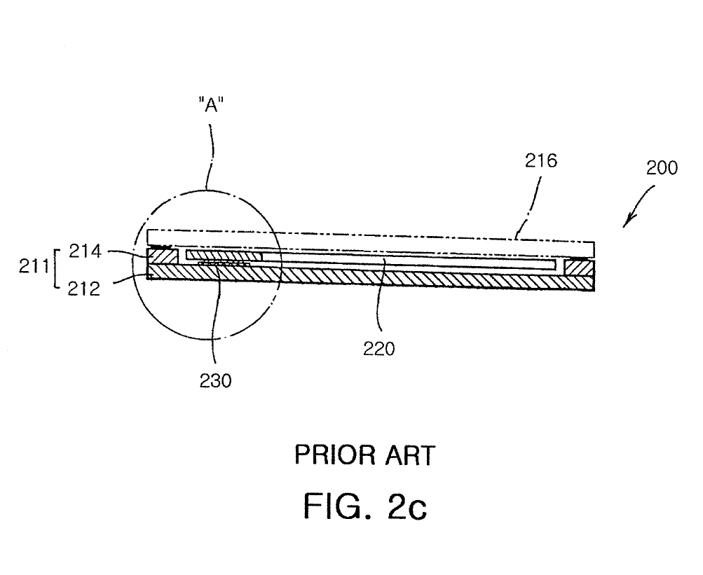

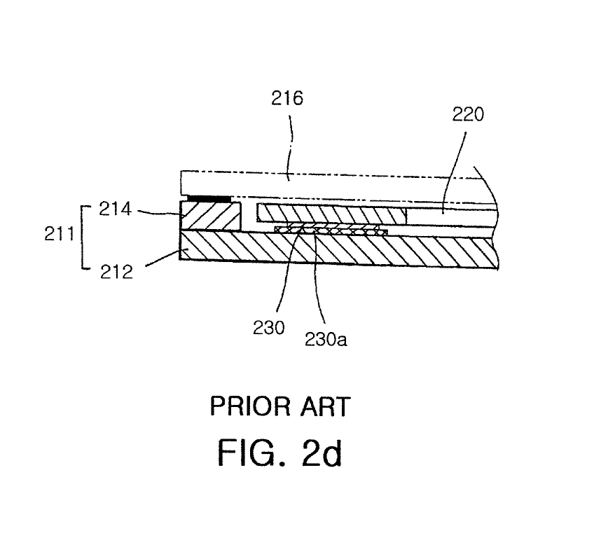

In the quartz crystal oscillator 500 having the double-layered ceramic base of this invention, the oscillating plate 520 is directly mounted to the ceramic base 511 by means of a plurality of metal bumps 530 without using any protrusions of FIG. 1c or the tungsten bumps of FIG. 2c. Therefore, the quartz crystal oscillator 500 having the double-layered ceramic base of this invention is remarkably different from the conventional quartz crystal oscillators in their structures. The quartz crystal oscillator 500 preferably reduces its thickness, thus accomplishing the recent trend of compactness, smallness, lightness and thinness of the quartz crystal oscillators.

As described above, the present invention may be preferably adapted to quartz crystal oscillators regardless of the types of the oscillator plates. Particularly, the present invention is more preferably adapted for manufacturing a tuning fork-type quartz crystal oscillator, which necessarily maintains a vacuum in its interior so as to prevent its oscillating plate from coming into frictional contact with air during its oscillating action.

A better understanding of the present invention may be obtained through the following example which is set forth to illustrate, but is not to be construed to limit the present invention. For example, it should be understood that the electrode patterns may be somewhat freely designed in accordance with the characteristics of resulting quartz crystal oscillators.

### EXAMPLE

Slurry was produced by mixing ceramic power. A green sheets were produced using the slurry. A triple-layered ceramic base was produced using the green sheets. A Z-cut quartz crystal blank was prepared to wash, and subjected to a printing process, thus producing a quartz crystal oscillating plate. Four gold bumps, each having a size of 100μm, were formed on electrode terminals of protrusions of the ceramic base. Thereafter, the quartz crystal oscillating plate was laid on the bumps prior to mounting the plate to the ceramic base while pressing the plate and applying ultrasonic waves to the plate. In such a case, pressure of 2 kgf and ultrasonic waves generated by a sonicator were applied to the plate for a period of 250 msec while heating the plate at a temperature of about 200° C. and applying an electric current of 1.5 W to the plate, thus mounting the plate to the ceramic base. Thereafter, a little of electrodes on the oscillating plate was cut off using a laser beam, thus to regulating the frequency of the plate. Thereafter, the ceramic base was covered with a lid prior to forming a vacuum of about 10⁻²Torr, thus producing a desired quartz crystal oscillator of this invention.

The resulting oscillator of this invention and some conventional quartz crystal oscillators produced by mounting oscillating plates to ceramic bases using paste were commonly subjected to both a thermal shock test and a drop test. In addition, the variation in the frequency of the oscillators was measured after 48 hours had elapsed. The test results are given in Table 1.

In such a case, the thermal shock test was repeatedly performed 100 cycles while heating the quartz crystal oscillating plate at temperatures of −40° C. and 85° C. for 30 minutes for each temperature condition. The drop test was carried out for each side of each oscillator by dropping the oscillator from a height of 1.5 meters to the ground.

TABLE 1

| | After | | After | |
|---|---|---|---|---|
| | thermal | After drop | 48 hrs. | |
| Examples | shock test | test | in sealing | Remark |
| Ex. | −1 ˜ 3 Hz | −2 ˜ 4 Hz | 0 ˜ 4 Hz | Au bumps |
| Com.Ex. 1 | −6 ˜ 2 Hz | −2 ˜ 2 Hz | −4˜ 2 Hz | Si-based Ag |
| | | | | Paste |
| Com.Ex. 2 | −2 ˜ 9 Hz | 0 ˜ 15 Hz | −8 ˜ −25 Hz | Epoxy-based |
| | | | | Ag paste |

From the Table 1, it can be seen by those skilled in the art that the oscillator of this invention has a high thermal shock resistance, in addition to being less likely to vary in its frequency after the drop test. In addition, the oscillator according to this invention maintains its operational reliability regardless of lapse of time.

The conventional oscillator of the comparative example 1 produced using Si-based Ag paste is less likely to vary in its frequency after the drop test, but varies remarkably in its frequency after the thermal shock test or after the lapse of time. Therefore, it is noted that the conventional oscillator of comparative example 1 does not accomplish desired operational reliability. In addition, the conventional oscillator of the comparative example 2 produced using epoxy-based Ag paste varies remarkably in its frequency in each of the drop test, the thermal shock test and with the lapse of time.

As described above, the present invention provides a method of manufacturing quartz crystal oscillators, and a quartz crystal oscillator produced therefrom. The quartz crystal oscillator in the present invention is produced by mounting a quartz crystal oscillating plate to a ceramic base through an improved flip bonding process, thus having an improved reliability and being produced with high productivity, in addition to accomplishing the recent trend of compactness, smallness and thinness of such oscillators.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A method of manufacturing quartz crystal oscillators, comprising the steps of:
forming a ceramic base which a second ceramic layer and a third ceramic layer are sequentially laminated along the periphery of the top surface of a first ceramic layer, said ceramic base having a top cavity, wherein said top cavity is surrounded by said second ceramic layer and said third ceramic layer which are punched out so as to form protrusions partially extending from one side of said second ceramic layer, and said second ceramic layer having a predetermined electrode terminals on the protrusions;
preparing a quartz crystal oscillating plate having a predetermined electrode patterns;
disposing a plurality of metal bumps on the top surface of each of said electrode terminals on the protrusions of said second ceramic layer;
positioning said quartz crystal oscillating plate within said top cavity of the ceramic base and electrically connecting said quartz crystal oscillating plate with said metal bumps such that a remaining part of said quartz crystal oscillating plate except for the electrode terminals is spaced apart from said ceramic base by a gap; and
sealing said ceramic base with a ceramic lid.

2. The method according to claim 1, wherein said metal bumps are gold bumps.

3. The method according to claim 1, wherein the number of the metal bumps, formed on the top surface of said electrode terminal of each of said protrusions of the ceramic base corresponding to each electrode terminal of said oscillating plate, is two or more.

4. The method according to claim 1, wherein said metal bumps formed on said electrode terminals of the ceramic base occupy at least 20% of an entire area of said electrode terminals of the oscillating plate.

5. The method according to claim 4, wherein said metal bumps are formed on each electrode terminal of said ceramic base in a zigzag arrangement.

6. The method according to claim 1, wherein each of said metal bumps has a smooth top surface.

7. The method according to claim 6, wherein each of said metal bumps is formed by placing a metal wire on a predetermined position of said ceramic base, and compressing said metal wire under application of ultrasonic waves, and pulling said metal wire upward prior to compressing a top end of said metal wire so as to form the smooth top surface of each of said metal bumps.

8. The method according to claim 7, wherein each of said metal bumps is formed by applying pressure of about 250 g or less and ultrasonic waves to the bump for a period of about 50 msec or less while heating the bump at a temperature of about 300° C. or less and applying an electric current of about 2W or less to the bump.

9. The method according to claim 8, wherein each of said metal bumps is heated at a temperature of about 150˜250° C.

10. The method according to claim 6, wherein each of said metal bumps has both a smooth top portion and a smooth bottom portion, with a volume of said top portion being smaller than that of said bottom portion.

11. The method according to claim 10, wherein said smooth bottom portion of each of the metal bumps has a generally cylindrical shape with a diameter of about 50 μm or less and a height of about 40˜90 μm.

12. The method according to claim 1, wherein said quartz crystal oscillating plate is mounted to said ceramic base by pressing said plate to the metal bumps while applying mechanical frictional force caused by ultrasonic waves to said plate, thus electrically connecting the electrode terminals of said plate to said metal bumps.

13. The method according to claim 12, wherein pressure of about 2 kgf or less is applied to said oscillating plate under applying ultrasonic waves for a period of about 230 msec or less while heating said plate at a temperature of about 300° C. or less and applying an electric current of about 2 W or less to said plate.

14. The method according to claim 1, wherein said gap between said oscillating plate and the top surface of said first ceramic layer is about 10˜40 μm.

15. The method according to claim 1, wherein said quartz crystal oscillator is a tuning fork-type oscillator.

16. A method of manufacturing quartz crystal oscillators, comprising the steps of:
forming a ceramic base which a second ceramic layer is laminated along the periphery of a first ceramic layer, said ceramic base having a top cavity, wherein said top cavity is surrounded by said second ceramic layer which is punched out to form a rim, and said first ceramic layer having a predetermined electrode terminals at a desired position;
preparing a quartz crystal oscillating plate having a plurality of electrode patterns;
disposing a plurality of metal bumps on each of the electrode terminals of said first ceramic layer;
positioning said quartz crystal oscillating plate within the top cavity of said ceramic base and electrically connecting said quartz crystal oscillating plate with said metal bumps such that a remaining part of said quartz crystal oscillating plate except for said electrode terminals is spaced apart from said ceramic base by a gap; and
sealing said ceramic base with a ceramic lid.

17. The method according to claim 16, wherein said metal bumps are gold bumps.

18. The method according to claim 16, wherein the number of the metal bumps, formed on the top surface of each of said electrode terminals of the ceramic base corresponding to each electrode terminal of said oscillating plate, is two or more.

19. The method according to claim 16, wherein said metal bumps formed on said electrode terminals of the ceramic base occupy at least 20% of an entire area of said electrode terminals of the oscillating plate.

20. The method according to claim 18, wherein said metal bumps are formed on each electrode terminal of said ceramic base in a zigzag arrangement.

21. The method according to claim 16, wherein each of said metal bumps has a smooth top surface.

22. The method according to claim 21, wherein each of said metal bumps is formed by placing a metal wire on a predetermined position of said ceramic base, and compressing said metal wire under application of ultrasonic waves, and pulling said metal wire upward prior to compressing a top end of said metal wire so as to form the smooth top surface of each of said metal bumps.

23. The method according to claim 22, wherein each of said metal bumps is formed by applying pressure of about 250 g or less and ultrasonic wave to the bump for a period of about 50 msec or less while heating the bump at a temperature of about 300° C. or less and applying an electric current of about 2 W or less to the bump.

24. The method according to claim 23, wherein each of said metal bumps is heated at a temperature of about 150˜250° C.

25. The method according to claim 21, wherein each of said metal bumps has both a smooth top portion and a smooth bottom portion, with a volume of said top portion being smaller than that of said bottom portion.

26. The method according to claim 25, wherein said smooth bottom portion of each of the metal bumps has a generally cylindrical shape with a diameter of about 50 μm or less and a height of about 40˜90 μm.

27. The method according to claim 16, wherein said quartz crystal oscillating plate is mounted to said ceramic base by pressing said plate to the metal bumps while applying mechanical frictional force caused by ultrasonic waves to said plate, thus electrically connecting the electrode terminals of said plate to said metal bumps.

28. The method according to claim 16, wherein pressure of about 2 kgf or less is applied to said oscillating plate under applying ultrasonic waves for a period of about 230 msec or less while heating said plate at a temperature of about 300° C. or less and applying an electric current of about 2W or less to said plate.

29. The method according to claim 16, wherein said gap between said oscillating plate and the top surface of said first ceramic layer is about 10˜40 μm.

30. The method according to claim 16, wherein said quartz crystal oscillator is a tuning fork-type oscillator.

31. A quartz crystal oscillator, comprising:
a ceramic base laminated a second ceramic layer along the periphery of the top surface of a first ceramic layer, said ceramic base having a top cavity surrounded by said second ceramic layer, said first ceramic layer having a plurality of electrode terminals which are electrically connected to external electrodes at predetermined positions;
a quartz crystal oscillating plate having a plurality of electrode patterns, said oscillating plate being mounted to the electrode terminals of said first ceramic layer within said top cavity through a plurality of metal bumps such that a remaining part of said oscillating plate except for the terminals is spaced apart from said ceramic base by a gap; and
a ceramic lid covering said ceramic base to seal the oscillator.

32. The quartz crystal oscillator according to claim 31, wherein the number of said metal bumps, formed on the top surface of each of said electrode terminals of the ceramic base corresponding to each electrode terminal of said oscillating plate, is two or more.

33. The quartz crystal oscillator according to claim 31, wherein said metal bumps formed on said electrode terminals of said ceramic base occupy at least 20% of an entire area of said electrode terminals of the oscillating plate.

34. The quartz crystal oscillator according to claim 32, wherein said metal bumps are formed on each electrode terminal of said ceramic base in a zigzag arrangement.

35. The quartz crystal oscillator according to claim 31, wherein said metal bumps are gold bumps.

36. The quartz crystal oscillator according to claim 31, wherein said gap between said oscillating plate and the top surface of said first ceramic layer of the ceramic base is about 10˜40 μm.

37. The quartz crystal oscillator according to claim 31, wherein said quartz crystal oscillator is a tuning fork-type oscillator.
